(19) United States
(12) Patent Application Publication
(10) Pub. No.: US 2015/0249052 A1
(43) Pub. Date: Sep. 3, 2015

(54) SEMICONDUCTOR DEVICE

(71) Applicant: Noriaki IKEDA, Chuo-ku, Tokyo (JP)

(72) Inventor: Noriaki Ikeda, Tokyo (JP)

(21) Appl. No.: 14/427,440

(22) PCT Filed: Sep. 6, 2013
(86) PCT No.: PCT/JP2013/074779

§ 371 Date: Mar. 11, 2015

(30) Foreign Application Priority Data
Sep. 11, 2012 (JP) 2012-199458

(51) Int. Cl. H01L 23/535; H01L 27/105

(52) U.S. Cl. CPC H01L 23/535; H01L 27/1052

(57) ABSTRACT

The semiconductor device according to the present invention comprises: a memory cell region formed on a semiconductor substrate; peripheral circuit regions formed at the periphery of the memory cell region; embedded wiring lines formed embedded in trench portions formed in the semiconductor substrate; and upper wiring lines formed in a layer above the memory cell region and the peripheral circuit regions, and peripheral circuits in the peripheral circuit regions are connected to the upper wiring lines by way of the embedded wiring lines.

### TECHNICAL FIELD

The present invention relates to a semiconductor device.

### BACKGROUND ART

One problem that arises as miniaturization of semiconductor devices such as DRAM (Dynamic Random Access Memory) progresses is the problem that the channel length of the MOS (Metal Oxide Semiconductor) transistors which form the memory cells and the like is reduced, and it thus becomes difficult to suppress short channel effects.

Patent literature article 1 (Japanese Patent Kokai 2011-129566) discloses a technique in which a trench portion is provided in a semiconductor substrate in a memory cell region in which memory cells are disposed, a gate insulating film is formed on the inner wall surfaces of the trench portion, a gate electrode is formed by embedding a gate electrode material on the gate insulating film, and the gate electrode is used as a word line. According to this technique, the surface of the trench portion is used as the channel, and therefore the amount by which the channel length dimension in the planar direction is reduced concomitant with miniaturization can be compensated for by an enlargement in the dimension in the depth direction, and therefore short channel effects can be suppressed.

### PRIOR ART LITERATURE

### Patent Literature

Patent literature article 1: Japanese Patent Kokai 2011-129566

### SUMMARY OF THE INVENTION

### Problems to be Resolved by the Invention

In a semiconductor device, memory cells, and peripheral circuits for reading and writing information to and from the memory cells, for example, are generally formed on a semiconductor substrate. The peripheral circuits are formed at the periphery of a memory cell region in which the memory cells are formed. Further, upper wiring lines are formed in layers above the memory cell region and a peripheral circuit region in which the peripheral circuits are formed. It should be noted that examples of upper wiring lines include power source wiring lines for supplying power (VDD, VSS) to the peripheral circuits, and signal transmission wiring lines for transmitting signals.

Another problem that arises as miniaturization of semiconductor devices progresses is the problem that it is difficult to secure availability of a wiring line area for the upper wiring lines. In order to supply power or to transmit signals to a peripheral circuit, upper wiring lines are normally routed to the vicinity of the peripheral circuit. For example, if a power supply voltage which has been supplied to a pad on a chip is being supplied by means of a mesh-like upper wiring line, a lower layer wiring line is routed to circuit elements which need to be supplied from this power source, and contact is made with the upper wiring line. However, when the chip surface area decreases as miniaturization of semiconductor devices progresses, there is also a demand for the wiring line area used for routing upper wiring lines to the vicinity of the peripheral circuits to be reduced. With the technique disclosed in patent literature article 1, the element surface area can be reduced while the short channel effect is suppressed, but a reduction in the wiring line area for upper wiring lines discussed hereinabove is not taken into account.

### Means of Overcoming the Problems

A semiconductor device according to one aspect of the present invention comprises:

a memory cell region in which a memory cell array is formed;

a peripheral circuit region in which peripheral circuits are formed;

a plurality of embedded wiring lines formed embedded in a semiconductor substrate; and

upper wiring lines formed in an upper wiring line layer above the memory cell region and the peripheral circuit region; and

the plurality of embedded wiring lines are formed corresponding to rows in the memory cell array, and some of the plurality of embedded wiring lines are used as word lines, and the embedded wiring lines other than the embedded wiring lines used as the word lines are used as dummy word lines connecting the upper wiring lines to the peripheral circuits in the peripheral circuit.

A semiconductor device according to another aspect of the present invention comprises:

a memory cell region in which a memory cell array is formed;

a peripheral circuit region in which peripheral circuits are formed;

a plurality of embedded wiring lines formed embedded in a semiconductor substrate; and

upper wiring lines formed in an upper wiring line layer above the memory cell region and the peripheral circuit region; and

the plurality of embedded wiring lines are formed corresponding to rows in the memory cell array, and

in the plurality of embedded wiring lines, the embedded wiring lines formed in a first region in the memory cell region are used as word lines, and the embedded wiring lines formed in a second region in the memory cell region outside the first region are used as dummy word lines connecting the upper wiring lines to the peripheral circuits in the peripheral circuit.

A semiconductor device according to yet another aspect of the present invention comprises:

a first embedded wiring line which is formed embedded in a semiconductor substrate in a memory cell region and is used as a word line, and

a second embedded wiring line which is formed embedded in the semiconductor substrate and is used as a wiring line for operating a circuit in the semiconductor device.

### Advantages of the Invention

According to the present invention, the embedded wiring lines formed in such a way that they are embedded in the semiconductor substrate serve as a substitute for the upper wiring lines, and the peripheral circuits and the upper wiring lines are connected by way of the embedded wiring lines, and it is therefore no longer necessary to route upper wiring lines, and the wiring line area of the upper wiring lines can be reduced.

### BRIEF EXPLANATION OF THE DRAWINGS

FIG. 1 is a drawing illustrating the layout configuration of a semiconductor device studied in advance by the inventor of this application.

FIG. 2 is a top view of a memory cell region illustrated in FIG. 1.

FIG. 3A illustrates the main parts in a cross-sectional view along the line A-A′ shown in FIG. 2, as viewed in the direction of the arrows.

FIG. 3B illustrates the main parts in a cross-sectional view along the line B-B′ shown in FIG. 2, as viewed in the direction of the arrows.

FIG. 4 is a drawing illustrating the schematic configuration of a semiconductor device according to a first mode of embodiment of the present invention.

FIG. 5 is a drawing illustrating the layout configuration of the semiconductor device according to the first mode of embodiment of the present invention.

FIG. 6 is a top view of the vicinity of a dummy region illustrated in FIG. 5.

FIG. 7A illustrates the main parts in a cross-sectional view along the line A-A′ shown in FIG. 6, as viewed in the direction of the arrows.

FIG. 7B illustrates the main parts in a cross-sectional view along the line B-B′ shown in FIG. 6, as viewed in the direction of the arrows.

FIG. 8 is a drawing illustrating an example of the layout configuration of the semiconductor device illustrated in FIG. 5.

FIG. 9A is a drawing illustrating an example of the arrangement of the upper wiring lines in the semiconductor device illustrated in FIG. 5.

FIG. 9B is a drawing illustrating an example of the arrangement of the upper wiring lines in the semiconductor device illustrated in FIG. 5.

FIG. 9C is a drawing illustrating an example of the arrangement of the upper wiring lines in the semiconductor device illustrated in FIG. 5.

FIG. 10 is a top view of the vicinity of a dummy region in a semiconductor device according to a second mode of embodiment of the present invention.

FIG. 11 illustrates the main parts in a cross-sectional view along the line A-A′ shown in FIG. 10, as viewed in the direction of the arrows.

### MODES OF EMBODYING THE INVENTION

Modes of embodying the present invention will now be described with reference to the drawings.

### First Mode of Embodiment

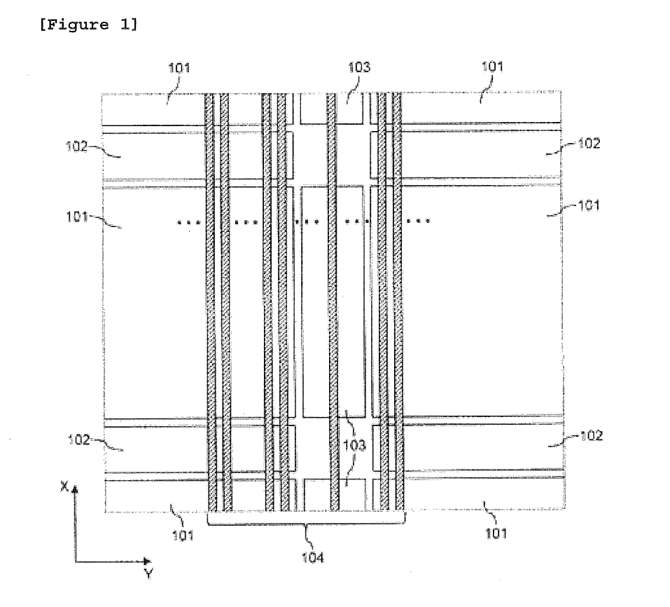

With reference to FIGS. 1 to 3, first a description will be provided regarding the configuration of a semiconductor device which the inventor of this application studied in advance, as a prior-study example in which gate electrodes embedded in a semiconductor substrate are used as word lines.

FIG. 1 is a drawing illustrating the layout configuration of the semiconductor device in the prior-study example.

As illustrated in FIG. 1, the semiconductor device in the prior-study example comprises memory cell regions 101 in which memory cells are formed, and row control system circuit regions 102 and column control system circuit regions 103 disposed surrounding the memory cell regions 101. The row control system circuit regions 102 and the column control system circuit regions 103 are peripheral circuit regions in which peripheral circuits for writing or reading information to or from the memory cells, for example, are formed. Each memory cell region 101 block is operated under the control of the peripheral circuits disposed in a single row control system circuit region 102 and the peripheral circuits disposed in a single column control system circuit region 103. These blocks are also referred to as memory mats, for example.

A plurality of word lines (which are not shown in the drawings) extending in the X-direction (the row direction) and a plurality of bit lines (which are not shown in the drawings) extending in the Y-direction (the column direction) are formed in the memory cell region 101. Further, memory cells are formed at the points of intersection between each word line and each bit line in the memory cell region 101, the memory cells being formed in a matrix (array). One memory cell can be accessed by selecting a pair comprising a word line and a bit line. Such a disposition of memory cells is known as a memory cell array.

The row control system circuit regions 102 are formed facing the end portions in the X-direction of the memory cell region 101. Peripheral circuits such as sub-word drivers and main-word drivers are formed in the row control system circuit regions 102.

The column control system circuit regions 103 are formed facing the end portions in the Y-direction of the memory cell region 101. Peripheral circuits such as sense amplifiers, Y-switches, precharge circuits are provided in the column control system circuit regions 103.

Upper wiring lines 104 are formed in layers (upper wiring line layers) above the memory cell regions 101 and the peripheral circuit regions (the row control system circuit regions 102 and the column control system circuit regions 103). The upper wiring lines 104 include, for example, power source wiring lines for supplying power (VDD, VSS) to the peripheral circuits, and signal transmission wiring lines for transmitting storage information and control signals. It should be noted that in FIG. 1 the upper wiring lines 104 are hatched, for clarity. Further, FIG. 1 depicts only a layer, from within the upper wiring line layer, in which wiring lines extending in the X-direction are provided, but layers in which wiring lines extending in the Y-direction are provided, and layers in which wiring lines routed in both directions are provided, for example, are also formed in other layers formed above and below the layer depicted in the drawing. Such upper wiring lines are sometimes arranged in the same layer, and sometimes formed separately in multiple layers. If it is necessary for wiring lines in an upper and a lower layer to be electrically connected to each other, a conductor plug (via plug) is formed in a position corresponding to the point of intersection of the wiring lines that are to be electrically connected, in a layer between the wiring line layers in which the wiring lines to be electrically connected are formed, and the wiring lines are connected to each other by way of the conductor plug (via plug). If it is necessary for a circuit element or a wiring line (for example a gate wiring line, a word line, a bit line or the like) formed on the substrate surface to be electrically connected to an upper wiring line, a conductor plug (contact plug) is formed in the layer between said wiring line layer and the substrate surface, and the circuit element or wiring line formed on the substrate surface is connected to the upper wiring line by way of the conductor plug.

As illustrated in FIG. 1, the wiring lines 104 formed in the upper wiring line layer have what is known as a line and space (L/S) construction in which said wiring lines 104 extend in the X-direction and are arranged at prescribed intervals in the Y-direction. L/S constructions, in which an identical shape is repeated at equal periods, can be formed easily using photolithography or etching etc., and are suited to being formed as fine patterns.

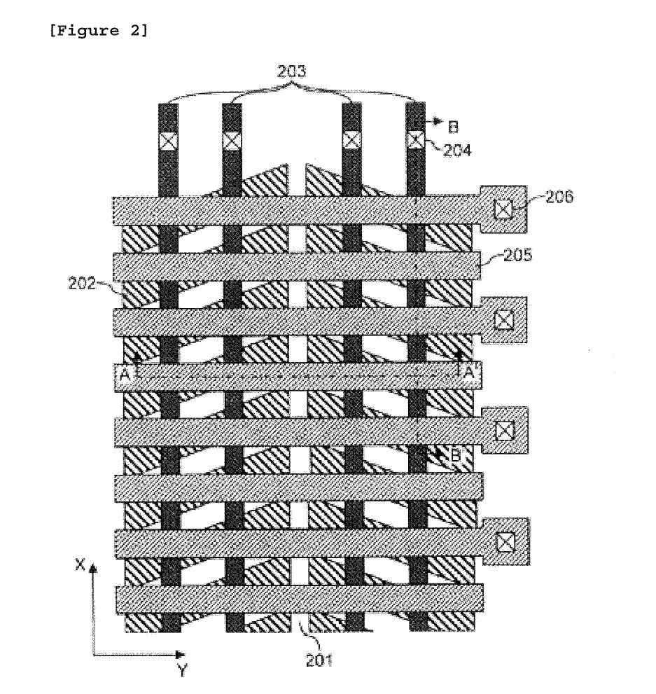

FIG. 2 is a top view of a memory cell region illustrated in FIG. 1. It should be noted that in FIG. 2 the upper wiring lines have been omitted. Further, in FIG. 2 each component is hatched in order to differentiate each component and to improve the clarity of the drawing.

A plurality of active regions 202 surrounded by shallow-trench type (STI: Shall Trench Isolation type) element isolation portions 201 are formed on the semiconductor substrate. Further, a plurality of gate electrodes (203) extending in the X-direction are formed in such a way as to intersect the plurality of active regions 202. The gate electrodes (203) are used as word lines, and they are therefore referred to hereinafter as word lines 203. In this prior-study example, a construction formed in such a way that two word lines 203 intersect one active region 202 is shown by way of example. Further, a construction in which the active regions 202 and the word lines 203 intersect obliquely, not at right angles, is shown by way of example.

The word lines 203 are connected via contact plugs 204 to wiring lines (which are not shown in the drawings) in the upper wiring line layer, and are connected via these wiring lines to peripheral circuits in the row control system circuit region 102. The word lines 203 are, for example, connected to the sub-word drivers, from among the peripheral circuits in the row control system circuit region 102, and are controlled by the sub-word drivers, the main-word drivers or the like. In other words, the word lines 203 are activated by the sub-word drivers or the like in accordance with reading or writing of information to or from a memory cell.

Bit lines 205 are formed extending in the Y-direction, intersecting the active regions 202 and the word lines 203. In this prior-study example, a construction in which the active regions 202 and the bit lines 205 intersect obliquely, not at right angles, is shown by way of example. Further, a construction in which the word lines 203 and the bit lines 205 intersect at right angles is shown by way of example. The bit lines 205 are connected via contact plugs 206 to wiring lines (which are not shown in the drawings) in the upper wiring line layer, and are connected via these wiring lines to peripheral circuits in the column control system circuit region 103. The bit lines 205 are, for example, connected to the Y-switches, from among the peripheral circuits in the column control system circuit region 103, and are controlled by the sense amplifiers, the precharge circuits or the like.

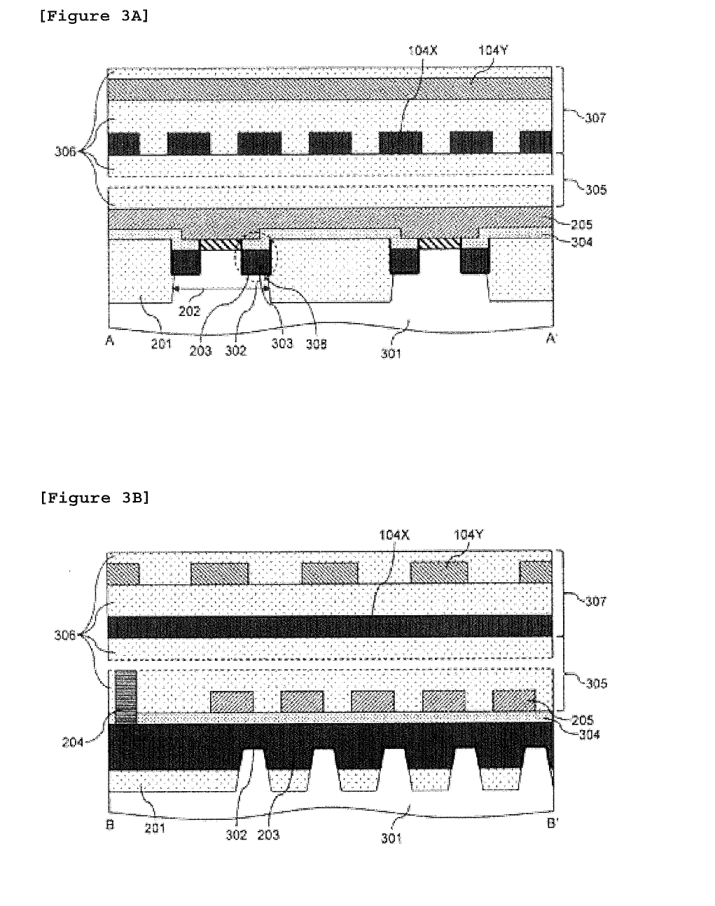

FIG. 3A illustrates the main parts in a cross-sectional view along the line A-A′ in FIG. 2, as viewed in the direction of the arrows. Further, FIG. 3B illustrates the main parts in a cross-sectional view along the line B-B′ in FIG. 2, as viewed in the direction of the arrows. In FIGS. 3A and 3B, the same reference codes have been appended to components that are the same as in FIGS. 1 and 2.

As illustrated in FIGS. 3A and 3B, shallow trenches formed in the semiconductor substrate 301 are filled with an insulating material such as silicon dioxide or silicon nitride, to form element isolation portions 201 having what is known as an STI structure. The element isolation portions 201 having an STI structure are formed surrounding a prescribed region of the main surface of the substrate in such a way as to demarcate said region. Circuit elements and the like are formed in the regions surrounded by the element isolation portions 201. The regions demarcated by the element isolation portions 201 are referred to as active regions 202.

Trench portions 302 are formed in the semiconductor substrate within the active regions 202. A gate insulating film 303 is formed on the inner wall surfaces of the trench portions 302. A conductor film 308 is embedded in the trench portions 302, with the interposition of the gate insulating film 303. Thus in this prior-study example an MIS structure comprising a metal portion (Metal), an insulator portion (Insulator) and a semiconductor portion (Semiconductor) is formed in such a way that it is embedded in the semiconductor substrate 301. The MIS structure forms the main part of an MIS transistor. In other words, the gate structure of the MIS transistor is formed in such a way that it is embedded in the semiconductor substrate 301. As discussed hereinabove, the gates of the transistors in a memory cell array function as word lines, and therefore in this prior-study example, word lines 203 are formed in such a way that they are embedded in the semiconductor substrate 301. The gate insulating film 303 is formed using an insulating film comprising silicon dioxide, silicon nitride, silicon oxynitride or the like, for example. Further, the conductor film 308 is formed using a conductor film (metal) comprising tungsten, tungsten nitride, conductive polysilicon (also known as polycrystalline silicon) or the like, for example.

The surface of the semiconductor substrate 301 is covered by an interlayer insulating film 304. In other words, the interlayer insulating film 304 is formed in such a way that it covers the abovementioned components (the element isolation portions 201, the active regions 202, the word lines 203 and the like) formed in the semiconductor substrate 301. The interlayer insulating film 304 is formed using silicon dioxide, silicon nitride or the like, and it insulates the components above and below the interlayer insulating film 304 from each other. In the present prior-study example, the bit lines 205 are then formed on the interlayer insulating film 304. The bit lines 205 are formed for example using conductive polysilicon, metal or the like. Holes are provided in desired locations in the interlayer insulating film 304. The holes provided in the interlayer insulating film 304 make it possible to connect components above the interlayer insulating film 304 to components below the interlayer insulating film 304. This prior-study example shows by way of example a configuration in which holes are provided in portions of the interlayer insulating film 304 covering the active regions 202, and the bit lines 205 and the memory cells are connected at the positions in which these holes are provided.

Further, a lower wiring line layer 305 and an upper wiring line layer 307 which form a multilayer wiring layer are formed on the bit lines 205. Intermediate layers in the lower wiring line layer 305 are omitted from FIGS. 3A and 3B. Wiring lines and plugs (for example the bit lines 205, the contact plugs 204, the wiring lines 104 and the like) are formed in interlayer insulating films 306 in the multilayer wiring layer. Further, capacitative elements (which are not shown in the drawings) may also be included into the lower wiring line layer 305.

Upper wiring lines 104X extending in the X-direction, and upper wiring lines 104Y extending in the Y-direction are formed with the interlayer insulating films 306 therebetween in the upper wiring line layer 307.

As described with reference to FIG. 1, in the semiconductor device in this prior-study example power and signals are transmitted by means of the upper wiring lines 104, which have an L/S construction and are disposed on the memory cell regions 101 and the peripheral circuit regions 102, 103. In response to demands for semiconductor devices to be miniaturized, even such transmission wiring lines have been the subject of attempts to reduce the respective dimensions of L (the wiring lines) and S (the spaces between the wiring lines), and to minimize the wiring distances by altering the element layout, for example. It is however necessary to satisfy demands for further miniaturization.

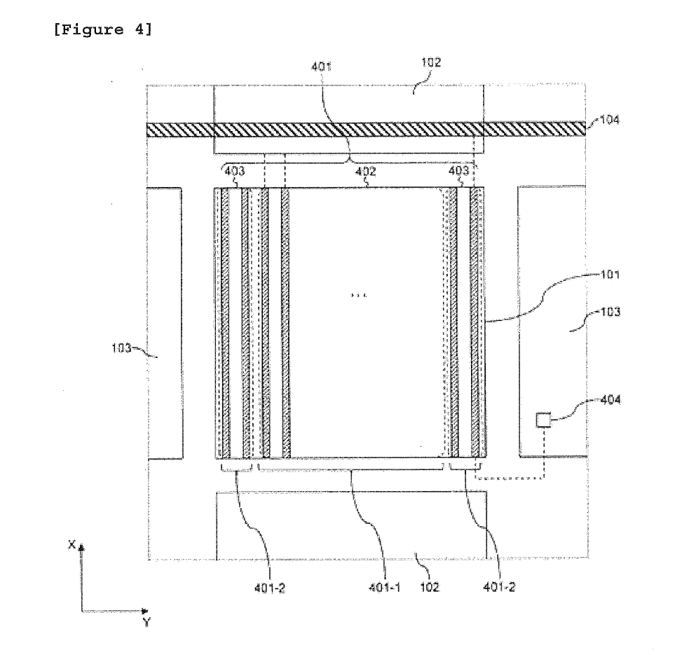

Accordingly, the configuration of the semiconductor device according to the first mode of embodiment of the present invention will now be described with reference to FIGS. 4 to 7.

The schematic configuration of the semiconductor device according to this mode of embodiment will be described first with reference to FIG. 4.

FIG. 4 is a layout drawing illustrating the schematic configuration of the semiconductor device according to this mode of embodiment of the present invention. It should be noted that the same reference codes are appended hereinafter to components that are the same as in FIGS. 1 to 3, and descriptions thereof are omitted. Further, in FIG. 4, which is a top view, some components are hatched in order to improve the clarity of the drawing.

As illustrated in FIG. 4, the semiconductor device according to this mode of embodiment comprises the memory cell region 101 in which a memory cell array is formed, and the row control system circuit regions 102 and the column control system circuit regions 103 disposed surrounding the memory cell region 101. The row control system circuit regions 102 and the column control system circuit regions 103 are peripheral circuit regions in which peripheral circuits for writing or reading information to or from the memory cells, for example, are formed.

Further, the upper wiring lines 104, which are wiring lines for operating the peripheral circuits, are formed in layers above the memory cell regions 101 and the peripheral circuit regions (the row control system circuit regions 102 and the column control system circuit regions 103). The upper wiring lines 104 include, for example, power source wiring lines for supplying power to the peripheral circuits, and signal transmission wiring lines for transmitting storage information and control signals. It should be noted that FIG. 4 depicts only a layer, from within the upper wiring line layer, in which wiring lines extending in the Y-direction are provided. However, layers in which wiring lines extending in the X-direction are provided, and layers in which wiring lines routed in both directions are provided, for example, are also formed above and below the layer depicted in the drawing.

Further, a plurality of embedded wiring lines 401, which extend in the X-direction (the row direction) and are embedded in the semiconductor substrate, are formed in the semiconductor device according to this mode of embodiment.

Here, each of the plurality of embedded wiring lines 401 is formed corresponding to a row in a memory cell array in the memory cell region 101. From among the plurality of embedded wiring lines 401, embedded wiring lines 401-1 formed in a prescribed region 402 within the memory cell region 101 are connected to peripheral circuits (sub-word drivers) in the row control system circuit regions 102, and are used as the word lines 203. It should be noted that the embedded wiring lines 401 formed in the prescribed region 402 within the memory cell region 101 are connected to the peripheral circuits in the row control system circuit regions 102 by way of lower wiring lines, contact plugs and the like formed in a lower wiring line layer which is below the upper wiring line layer in which the upper wiring lines 104 are formed. The components for connecting the embedded wiring lines 401-1 to the peripheral circuits in the row control system circuit regions 102 are omitted from FIG. 4.

Further, from among the plurality of embedded wiring lines 401, embedded wiring lines 401-2, formed in regions 403 other than the region 402 in the memory cell region 101, are used as wiring lines (dummy word lines) connecting the upper wiring lines 104 to peripheral circuits 404 in the peripheral circuit regions (the row control system circuit regions 102 and the column control system circuit regions 103). It should be noted that details of the connections between the upper wiring lines 104 and the dummy word lines, and details of the connections between the dummy word lines and the peripheral circuits 404, are discussed hereinafter.

As discussed hereinabove, the upper wiring lines 104 are wiring lines for operating the peripheral circuits, such as power source wiring lines for supplying power to the peripheral circuits, and signal transmission wiring lines for transmitting storage information and control signals. The upper wiring lines 104 are connected to the peripheral circuits 404 by way of the dummy word lines (the embedded wiring lines 401-2), and thus power is supplied to the peripheral circuits 404, or storage information and control signals are transmitted to the peripheral circuits 404, from the upper wiring lines 104 via the embedded wiring lines 401-2. In other words, the dummy word lines (the embedded wiring lines 401-2) are used as wiring lines for operating the peripheral circuits 404.

Thus the semiconductor device according to this mode of embodiment comprises the memory cell region 101, the peripheral circuit regions (the row control system circuit regions 102 and the column control system circuit regions 103), the plurality of embedded wiring lines 401 formed embedded in the semiconductor substrate, corresponding to the rows in the memory cell array within the memory cell region 101, and the upper wiring lines 104. Further, in the semiconductor device according to this mode of embodiment, some of the plurality of embedded wiring lines 401, namely the embedded wiring lines 401-1, are used as word lines, and the embedded wiring lines 401-2 other than the embedded wiring lines 401-1 are used as wiring lines (dummy word lines) connecting the upper wiring lines 104 to the peripheral circuits 404 in the peripheral circuit regions.

In other words, the semiconductor device according to this mode of embodiment comprises the memory cell region 101, the peripheral circuit regions (the row control system circuit regions 102 and the column control system circuit regions 103), the plurality of embedded wiring lines 401 formed embedded in the semiconductor substrate, corresponding to the rows in the memory cell array within the memory cell region 101, and the upper wiring lines 104. Further, in the semiconductor device according to this mode of embodiment, the embedded wiring lines 401-1 formed in the region 402, which serves as a first region in the memory cell region 101, are used as word lines, and the embedded wiring lines 401-2 formed in the regions 403, which serve as second regions in the memory cell region 101 and which are regions in the memory cell region 101 outside the first region, are used as wiring lines (dummy word lines) connecting the upper wiring lines 104 to the peripheral circuits 404 in the peripheral circuit regions.

Further, to state this in a different way, the semiconductor device according to this mode of embodiment comprises the embedded wiring lines 401-1, serving as first embedded wiring lines which are formed embedded in the semiconductor substrate within the memory cell region 101 and are used as word lines, and the embedded wiring lines 401-2, serving as second embedded wiring lines which are formed embedded in the semiconductor substrate and are used as wiring lines for operating the peripheral circuits 404, which are circuits in the semiconductor device.

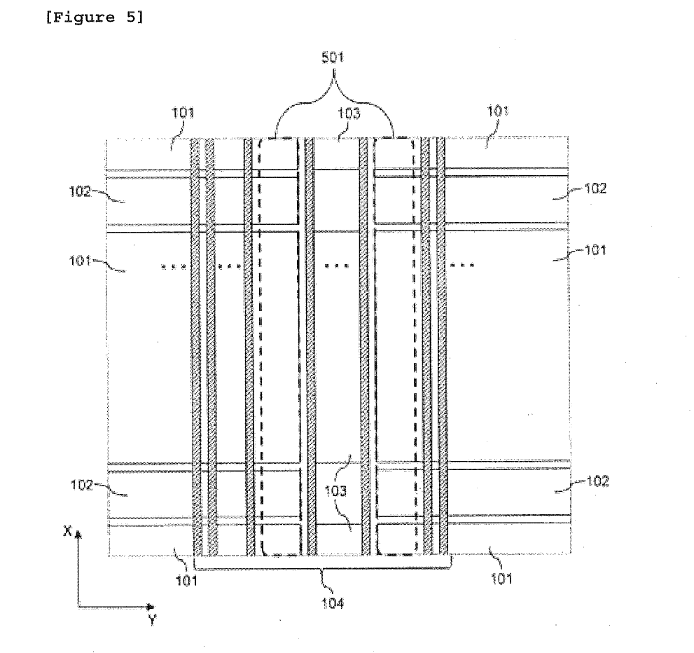

Details of the configuration of the semiconductor device in this mode of embodiment will be described next with reference to FIG. 5 to FIG. 7.

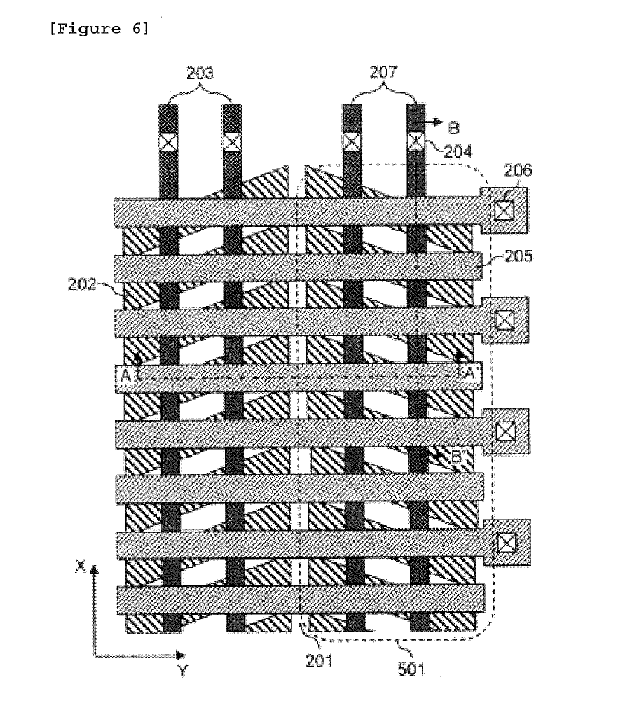

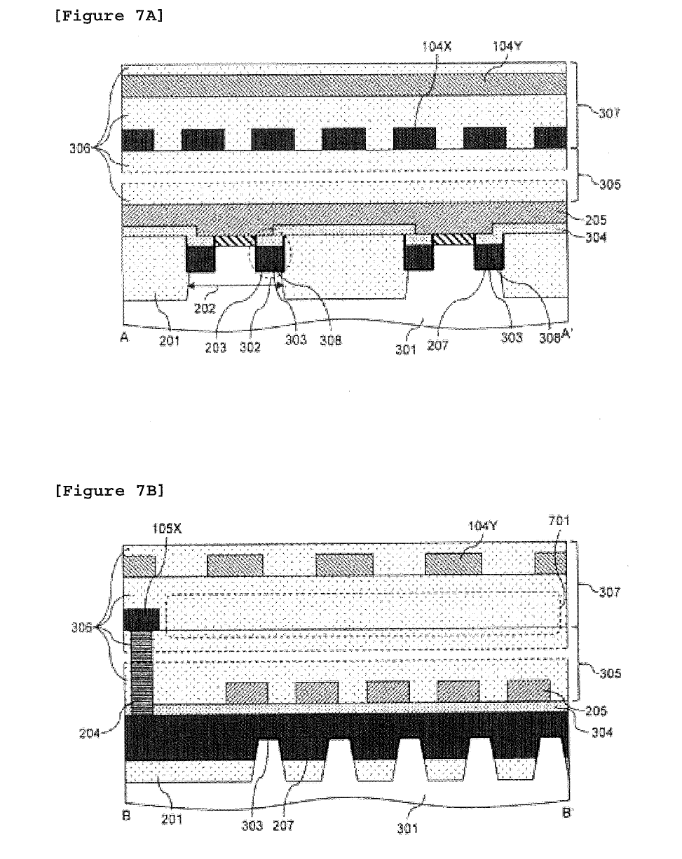

FIG. 5 is a drawing illustrating the layout configuration of the semiconductor device according to this mode of embodiment. FIG. 6 is a top view illustrating the memory cell region in FIG. 5, in particular illustrating the vicinity of the end portion, in the Y-direction, of the mat. FIG. 7A illustrates the main parts in a cross-sectional view along the line A-A′ in FIG. 6, as viewed in the direction of the arrows, and FIG. 7B illustrates the main parts in a cross-sectional view along the line B-B′ in FIG. 6, as viewed in the direction of the arrows. It should be noted that in FIGS. 5 and 6, which are top views, some components are hatched in order to improve the clarity of the drawings.

As illustrated in FIGS. 5 and 6, in the semiconductor device according to this mode of embodiment, memory cell rows disposed in the active regions 202 located in the end portions, in the Y-direction, of the memory cell region 101 are set as dummy cell rows to which information is not written. In other words, regions extending in the X-direction and having a prescribed width (the width of one active region) from the end portions, in the Y-direction, of the memory cell region 101 toward the inside of the memory cell region 101 are set as dummy regions 501. The dummy regions 501 correspond to the regions 403 which serve as the second regions in FIG. 4. Information is not written to the memory cells belonging to the dummy region 501. Thus the state of the connections between the word lines (referred to hereinafter as dummy word lines 207) formed in the dummy regions 501 and provided corresponding to the dummy cell rows, and the peripheral circuits in the row control system circuit regions 102, differs from the state of the connections of the other word lines 203. For example, the dummy word lines 207 are constructed in such a way that they are not connected to sub-word drivers and are not controlled by sub-word drivers. Other aspects of the configuration of the dummy word lines 207 are the same as for the other word lines 203. In other words, in the same way as with the word lines 203, the dummy word lines 207 are also formed in such a way that the trench portion 203 formed in the semiconductor substrate and extending in the X-direction is filled using the conductor film 308, with the interposition of the gate insulating film 303. As discussed hereinabove, in this mode of embodiment two word lines are disposed in one active region 202, and therefore the dummy word lines 207 are the two word lines at the end portion in the Y-direction of the memory cell region 101.

The periodic nature of the word lines 203 having an L/S construction is interrupted in the end portions in the Y-direction of the memory cell region 101. Generally, in L/S constructions formed by photolithography, etching or the like, patterning defects are liable to occur in the end portions of the pattern, where the periodic nature is interrupted. The pattern is liable to become thicker or thinner, for example. Increased resistance is a concern if the pattern becomes thinner. Further, a decrease in the pitch (and short-circuiting between wiring lines) is a concern if the pattern becomes thicker. Accordingly, by using as dummies the patterns formed in the end portions in the periodically-formed pattern of word lines, as in this mode of embodiment, it is possible to reduce the occurrence of failures arising due to the effects of patterning defects. In other words, by using as dummies the patterns formed in the end portions of the periodically-formed pattern of word lines, it is possible to reduce the impact of patterning defects on other constituent elements of the circuits. More specifically, by using as the dummy word lines 207 the word lines 203 in the end portions, in the Y-direction, of the memory cell region 101, the impact of patterning defects can be absorbed by said dummy word lines 207, preventing the word lines 203 from being affected.

Then, in this mode of embodiment the dummy word lines 207 formed in the dummy region 501 are used as a substitute for the upper wiring lines. In other words, the dummy word lines 207 are used as wiring lines for connecting the upper wiring lines to the peripheral circuits.

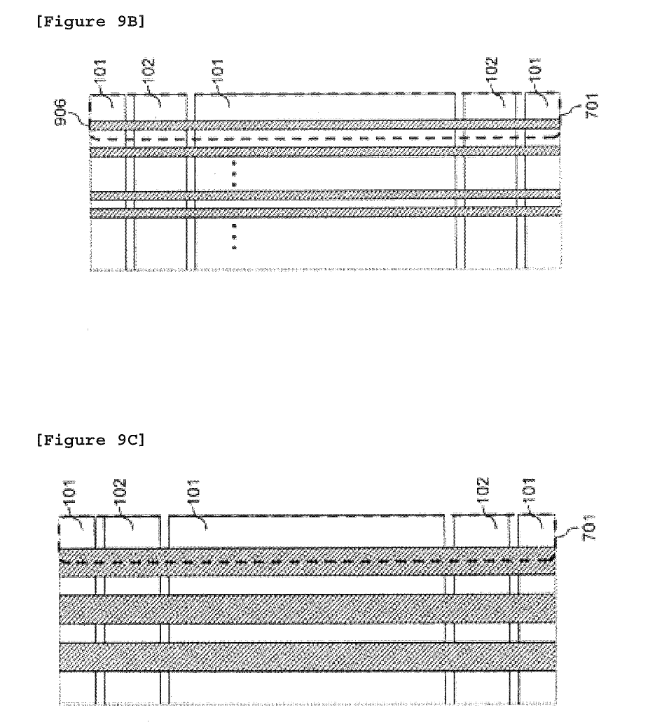

As illustrated in FIG. 7B, the dummy word line 207 formed in the dummy region 501 is connected to an upper wiring line 105X by way of the contact plug 204. If, for example, the dummy word line 207 is used as a substitute for an upper wiring line 104X, which extends in the X-direction as illustrated in FIG. 3B, then said upper wiring line 104X becomes redundant, and a wiring-line-free region 701 is created in the upper wiring line layer 307. A reduction in the space required for the wiring line layer can be achieved by filling the free region 701 with the other wiring lines. Further, the wiring-line-free region 701 can also be effectively utilized. Examples of ways to use the wiring-line-free region 701 will be described later with reference to FIG. 9.

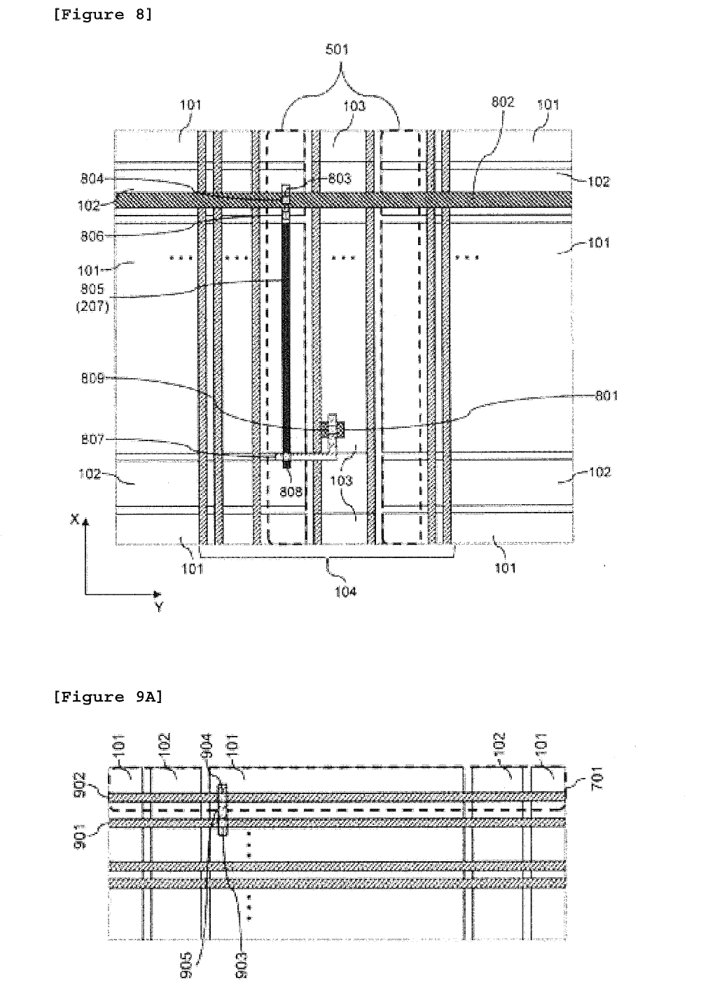

FIG. 8 is a drawing illustrating one example of the layout configuration of the semiconductor device according to this mode of embodiment. It should be noted that in FIG. 8 some components are hatched in order to improve the clarity of the drawing.

FIG. 8 is used to describe an example of a case in which power is supplied from an upper wiring line 802 extending in the Y-direction to a well power-supply portion 801 in the column control system circuit region 103. It is generally not the case that the active regions in which various circuit elements are disposed on a semiconductor substrate should all have the same construction, in consideration of element characteristics such as electrical polarity. Thus semiconductor regions having a desired impurity concentration are formed as wells. Then, in some cases power must be supplied in order to fix the potential of the well itself. Constraints on the layout of the elements make it difficult to dispose the well power-supply portion freely. Sometimes, therefore, the location through which the wiring line 802 supplying the power passes is remote from the location of the well power-supply portion 801, as in FIG. 8. In this case it is necessary to route a wiring line from the upper wiring line 802 to the vicinity of the well 801, and to connect the routed wiring line to the well power-supply portion 801 by way of a via plug, a contact plug or the like.

Here, in this mode of embodiment the routing of the upper wiring line can be omitted by connecting the well power-supply portion 801 to the upper wiring line 802 by means of a dummy word line 805 (207). More specifically, the upper wiring line 802 is connected by way of a via plug 804 to a tungsten wiring line 803 which serves as a first lower wiring line and is formed in the lower wiring line layer, and the tungsten wiring line 803 is connected to one end of the dummy word line 805 by way of a contact plug 806. Further, the other end of the dummy word line 805 is connected by way of a via plug 808 to a tungsten wiring line 807 which serves as a second lower wiring line and is formed in the lower wiring line layer, and the tungsten wiring line 807 is connected to the well power-supply portion 801 by way of a via plug 809. By this means it is possible to supply power from the upper wiring line 802 to the well power-supply portion 801 without routing an upper wiring line in the X-direction. In particular, the column control system circuit regions 103 are normally disposed outside the memory mat in the direction of the bit lines, in other words disposed along the dummy word lines and adjacent thereto, and therefore the dummy word lines are suited to serving as wiring lines to be routed to the well power-supply portion 801 in the column control system circuit region 103.

Thus in the semiconductor device according to this mode of embodiment, the embedded wiring lines (dummy word lines) which serve as the second embedded wiring lines and are formed in the dummy region 501 are used as a substitute for the upper wiring lines, and the peripheral circuits are connected to the upper wiring lines by way of the dummy word lines.

The routing of the upper wiring lines to the vicinity of the peripheral circuits can thus be omitted. Therefore the wiring line area for the upper wiring lines can be reduced, and a wiring-line-free region can be created in the upper wiring lines. The space required for the wiring line layer can thus be reduced, and the layout of the wiring line layer can be miniaturized. As a result the semiconductor device can be miniaturized further and its performance improved. Further, as described in detail hereinafter, the wiring-line-free region can also be effectively utilized.

By creating the wiring-line-free region 701 in the upper wiring line layer, a wiring line 902 for reinforcing a wiring line 901 such as an upper wiring line or a mesh wiring line can be disposed in the wiring-line-free region 701, as shown in FIG. 9A, for example. In this case the wiring line 901 is connected to the wiring line 902 by way of via plugs 903, 904 and a wiring line 905 formed in the lower wiring line layer. By this means the resistance of a power source wiring line can be reduced. Further, as illustrated in FIG. 9B an entirely different signal wiring line 906 can, for example, be disposed in the wiring-line-free region 701. By this means it is possible to achieve wider-band signal transmission and to increase the degree of freedom of the layout design. Further, as illustrated in FIG. 9C the upper wiring lines can be made thicker, or the pitch between the upper wiring lines can be made wider, for example. By this means it is possible to achieve a reduction in the resistance of the signal path, or a reduction in the cross-talk noise between wiring lines, for example. As described hereinabove, by forming a wiring-line-free region and utilizing the wiring-line-free region effectively, as in the semiconductor device according to this mode of embodiment, a semiconductor device with improved performance can be achieved.

### Second Mode of Embodiment

A semiconductor device according to a second mode of embodiment of the present invention differs from the semiconductor device according to the first mode of embodiment in that embedded wiring lines (dummy word lines) for connecting the upper wiring lines to the peripheral circuits are also formed in the element isolation portion 201 which isolates the memory cell region 101 from the column control system circuit region 103. It should be noted that descriptions of components that are the same as in the semiconductor device according to the first mode of embodiment are omitted.

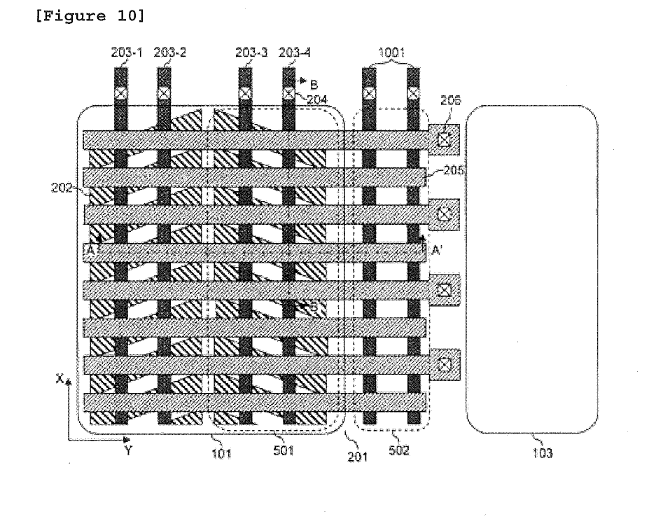

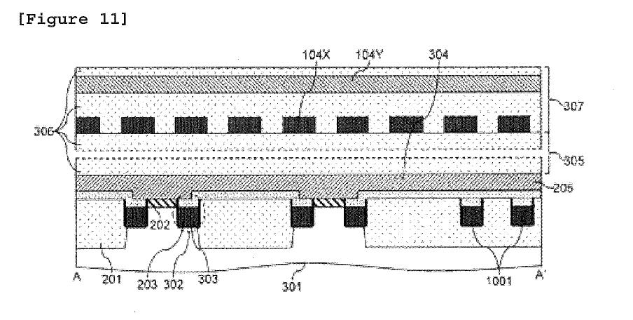

FIG. 10 is a top view of the vicinity of a dummy region in the semiconductor device according to this mode of embodiment. Further, FIG. 11 illustrates the main parts in a cross-sectional view along the line A-A′ shown in FIG. 10, as viewed in the direction of the arrows.

As illustrated in FIG. 10 and FIG. 11, in this mode of embodiment embedded wiring lines (dummy word lines) 1001 are also formed in the element isolation portion 201 which isolates the memory cell region 101 from the column control system circuit region 103, and these embedded wiring lines 1001 are also used as wiring lines for connecting the upper wiring lines to the peripheral circuits. Depending on the structure of the semiconductor device, in some cases it is not possible to form the memory cell region and the peripheral circuit regions using the same manufacturing process. For example, in some cases the gate structures in the peripheral circuit regions must be formed independently after the gate structures in the memory cell region have been formed. In this case, in order to protect the cell gate structures in the memory cell region that have already been formed from the effects of the thermal oxidation used to form the gate structures in the peripheral circuit regions, it is conceivable to maintain a wider element isolation between the memory cell region and the peripheral circuit regions.

Accordingly, in the semiconductor device according to this mode of embodiment an element isolation region is set as a dummy region 502 above the isolation portion, serving as a third region, and the embedded wiring lines (dummy word lines) 1001 are also formed in the dummy region 502 above the isolation portion. Then, in the same way as with the dummy word lines 207 in the first mode of embodiment, the dummy word lines 1001 formed in the dummy region 502 above the isolation portion are used as a substitute for the upper wiring lines. By this means the wiring-line-free region can be expanded further.

The dummy word lines 1001 formed in the element isolation portion 201 between the memory cell region 101 and the column region 103 are not in contact with the active region 202 used to form the elements inherently used as memory cells. Therefore the dummy word lines 1001 formed in the element isolation portion 201 can also be used as wiring lines for supplying electric potentials or signals for which there is concern that the memory cells will be affected.

Further, disposing the dummy word lines 1001 between the memory cell region 101 and the column control system circuit region 103 is also of value in terms of the manufacturing process. This is because the word lines 203 in the region actually used for memory cells are even more remote from the end portion of the L/S construction in which the pattern period is interrupted, and therefore the impact of patterning defects can be further reduced.

The dummy word lines 1001 disposed in the dummy region 502 above the isolation portion have the same construction as the dummy word lines 207, the only difference compared with the dummy word lines 207 in the first mode of embodiment being where they are disposed. To elaborate, the construction of the dummy word lines 1001 is such that they are not connected to the sub-word drivers, and are not controlled by the sub-word drivers. Then, in the same way as with the word lines 203, the dummy word lines 1001 are also formed in such a way that the trench portion 302 formed in the semiconductor substrate and extending in the X-direction is filled using the conductor film 308, with the interposition of the gate insulating film 303.

It should be noted that in this mode of embodiment a description was given of an example in which the dummy word lines are formed in both the dummy region 501 which serves as the second region and the dummy region 502 above the isolation portion which serves as the third region, and the dummy word lines are used as a substitute for the upper wiring lines, but it is also possible for only the dummy word lines formed in one or other of these regions to be used as a substitute for the upper wiring lines.

This application is based upon and claims the benefit of priority from Japanese Patent Application No. 2012-199458, filed on Sep. 11, 2012, the entire disclosure of which is incorporated herein by reference.

What is claimed is:

1. A semiconductor device comprising:
a memory cell region in which a memory cell array is formed;
a peripheral circuit region in which peripheral circuits are formed;
a plurality of embedded wiring lines formed embedded in a semiconductor substrate; and
upper wiring lines formed in an upper wiring line layer above the memory cell region and the peripheral circuit region; wherein
the plurality of embedded wiring lines are formed corresponding to rows in the memory cell array, and
some of the plurality of embedded wiring lines are used as word lines, and the embedded wiring lines other than the embedded wiring lines used as the word lines are used as dummy word lines connecting the upper wiring lines to the peripheral circuits in the peripheral circuit region.

2. The semiconductor device as claimed in claim 1, wherein:
the embedded wiring lines used as the dummy word lines are formed further to the outside of the memory cell region than the embedded wiring lines used as the word lines.

3. The semiconductor device as claimed in claim 1, wherein:
the embedded wiring lines used as the word lines are connected to sub-word drivers.

4. The semiconductor device as claimed in claim 1, wherein:
the embedded wiring lines used as the dummy word lines are connected to the upper wiring lines by way of first lower wiring lines formed in a lower wiring line layer that is above the memory cell region and the peripheral circuit region and is below the upper wiring line layer, and are connected to the peripheral circuits by way of second lower wiring lines formed in the lower wiring line layer.

5. The semiconductor device as claimed in claim 4, wherein:
the first and second lower wiring lines comprise tungsten wiring lines.

6. The semiconductor device as claimed in claim 1, wherein:
signals for controlling the operation of the peripheral circuits are supplied from the upper wiring lines to the embedded wiring lines used as the dummy word lines.

7. The semiconductor device as claimed in claim 1, wherein:
a power supply voltage for the peripheral circuits is supplied from the upper wiring lines to the embedded wiring lines used as the dummy word lines.

8. The semiconductor device as claimed in claim 1, wherein characterized in that:
the embedded wiring lines used as the dummy word lines are additionally formed in an isolation region which isolates the memory cell region from the peripheral circuit region.

9. A semiconductor device comprising:
a memory cell region in which a memory cell array is formed;
a peripheral circuit region in which peripheral circuits are formed;
a plurality of embedded wiring lines formed embedded in a semiconductor substrate; and
upper wiring lines formed in an upper wiring line layer above the memory cell region and the peripheral circuit region; wherein
the plurality of embedded wiring lines are formed corresponding to rows in the memory cell array, and
in the plurality of embedded wiring lines, the embedded wiring lines formed in a first region in the memory cell region are used as word lines, and the embedded wiring lines formed in a second region in the memory cell region outside the first region are used as dummy word lines connecting the upper wiring lines to the peripheral circuits in the peripheral circuit region.

10. The semiconductor device as claimed in claim 9, wherein:
the second region is disposed in the memory cell region, further to the outside than the first region.

11. The semiconductor device as claimed in claim 10, wherein:
the second region has a prescribed width in the row direction from an end portion in the column direction of the memory cell region.

12. The semiconductor device as claimed in claim 11, wherein:
the prescribed width is the width of one active region in which a memory cell is formed.

13. The semiconductor device as claimed in claim 11, wherein:
the second region comprises a region in which the memory cell in the endmost row of the memory cell array is formed.

14. The semiconductor device as claimed in claim 9, wherein:
information is not written into the memory cells in the second region.

15. The semiconductor device as claimed in claim 9, wherein:
the embedded wiring lines used as the dummy word lines are additionally formed in a third region which isolates the memory cell region from the peripheral circuit region.

16. A semiconductor device comprising:
a first embedded wiring line which is formed embedded in a semiconductor substrate in a memory cell region and is used as a word line, and
a second embedded wiring line which is formed embedded in the semiconductor substrate and is used as a wiring line for operating a circuit in the semiconductor device.

17. The semiconductor device as claimed in claim 16, wherein:
the second embedded wiring line is formed in the memory cell region.

18. The semiconductor device as claimed in claim 17, wherein:
the second embedded wiring line is formed in the memory cell region, further to the outside than the first embedded wiring line.

19. The semiconductor device as claimed in claim 17, wherein:
the second embedded wiring line is formed corresponding to the endmost row of the memory cell array in the memory cell region.

20. The semiconductor device as claimed in claim 16, wherein:
the second embedded wiring line is formed in an element isolation region which demarcates the memory cell region.
